(19) United States
(12) Patent Application Publication
(10) Pub. No.: US 2025/0324550 A1
(43) Pub. Date: Oct. 16, 2025

(54) HEATSINK WITH FINS ARRANGED IN A CONVERGENT-DIVERGENT PATTERN

(71) Applicant: Dell Products L.P., Round Rock, TX (US)

(72) Inventors: Ashish Shrivastava, Bangalore (IN); Sandeep Singh, Sonbhadra (IN)

(73) Assignee: Dell Products L.P., Round Rock, TX (US)

(21) Appl. No.: 18/636,537

(22) Filed: Apr. 16, 2024

(51) Int. Cl. H05K 7/20; G06F 1/20

(52) U.S. Cl. CPC H05K 7/2039; G06F 1/20; H05K 7/20154

(57) ABSTRACT

A heatsink has a base and fins disposed upon the base. The fins are configured to converge toward a center line of the heatsink so that, going from one side of the heatsink to the other, the fins converge and then diverge. As a result, the fins create air channels that are wider toward the sides of the heatsink and narrower at the centerline of the heatsink. The narrowness of the air channels, closer to the centerline, causes increased velocity of airflow, thereby providing relatively more heat removal.

### FIELD

The present disclosure relates to heatsinks and more particularly to heatsinks having fins that converge toward a centerline of the heatsink.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Further, as the value and use of information continues to increase, so does the value of the physical side of computing, including heat management.

### SUMMARY

In various embodiments, an apparatus includes: information handling system (IHS) includes: an information handling resource; a heatsink, coupled to the information handling resource, wherein the heatsink comprises a plurality of fins on a side of the heatsink away from the information handling resource, wherein the plurality of fins are configured to create a plurality of air channels that are narrower toward a center of the heatsink and wider toward a first edge and a second edge of the heatsink; and an air mover configured to drive airflow through the air channels.

In some embodiments, a heatsink includes: a flat base, wherein the flat base is configured as a six-sided polygon having a first side parallel to a second side, a third side and a fourth side forming a first V shape pointing inward toward a center of the heatsink, and a fifth side and a sixth side forming a second V shape pointing inward toward the center; and a plurality of fins coupled to the flat base, the plurality of fins converging from the first side toward a centerline of the heatsink and diverging from the centerline to the second side.

In some embodiments, a method includes: generating heat from an information handling resource in an information handling system (IHS), wherein the information handling resource is coupled to a heatsink; and operating an air mover to create airflow within the IHS, wherein the airflow is directed through a plurality of fins of the heatsink, wherein the fins are configured to create a plurality of air channels that are narrower toward a center of the heatsink and wider toward a first edge and a second edge of the heatsink.

### BRIEF DESCRIPTION OF THE DRAWINGS

The present disclosure may be better understood, and its numerous objects, features and advantages made apparent to those skilled in the art by referencing the accompanying drawings. The use of the same reference number throughout the several figures designates a like or similar element.

FIG. 1 is an illustration of an example heatsink, according to various embodiments.

FIG. 2 is a wired diagram illustration of the example heatsink of FIG. 1, according to various embodiments.

FIG. 3 is an illustration of an example air channel between two fins of the example heatsink of FIG. 1, according to various embodiments.

FIG. 4 is an illustration of the example heatsink of FIG. 1, coupled to an information handling resource, according to various embodiments.

FIG. 5 is an illustration of the example heatsink of FIG. 1 from another perspective, according to various embodiments.

FIG. 6 is an illustration of an example IHS, utilizing a heatsink having fins that create a con verging-diverging set of air channels, according to various embodiments.

FIG. 7 is an illustration of an example method of removing heat from an IHS, according to various embodiments.

### DETAILED DESCRIPTION

In the following description, numerous specific details are set forth in order to provide a thorough understanding of embodiments of the present disclosure. It will be apparent to one skilled in the art that embodiments of the present disclosure may be practiced without some of these specific details. Exemplary embodiments will now be described more fully hereinafter with reference to the accompanying drawings, in which exemplary embodiments are shown. This disclosure may, however, be embodied in many different forms and should not be construed as limited to the embodiments set forth herein. These embodiments are provided so that this disclosure will be thorough and complete and will fully convey the scope of the disclosure to those of ordinary skill in the art. Moreover, all statements herein reciting embodiments of the disclosure, as well as specific examples thereof, are intended to encompass both structural and functional equivalents thereof. Additionally, it is intended that such equivalents include both currently known equivalents as well as equivalents developed in the future (i.e., any elements developed that perform the same function, regardless of structure). While embodiments of the present disclosure have been illustrated and described, the disclosure is not limited to these embodiments only. Numerous modifications, changes, variations, substitutions, and equivalents will be apparent to those skilled in the art, without departing from the scope of the disclosure, as described in the claims.

Various implementations seek to enhance heat management of a computing system by implementing an improved heatsink design. Typically, a heatsink provides additional surface area for convective heat transfer. For instance, a heatsink may include a base with fins protruding perpendicular to the base. The fins may vary in height, pitch, and number based on the particulars of a given implementation. For relatively low power devices, a passive heatsink, which relies on system fans, may be appropriate for the task. By contrast, for relatively high-power devices, an active heatsink with dedicated fan, heat sink with a heat pipe or liquid cooling, may be more appropriate for the task.

Various heatsinks may include fins that create straight channels for airflow. The straight channels may have a same width dimension along an entire fin length. For instance, airflow may be directed toward the fins in a direction that is parallel to a length axis of the air channels. The airflow may dissipate heat along the length axis of the air channels.

It is generally accepted that heat transfer rate is dependent upon many physical parameters and one of those parameters is air velocity. When air flows between the heatsink fins (i.e., through the air channels created by the fins) the heat carrying capacity of the airflow may reduce from front to back due, at least in part, to reduction in air velocity. In other words, resistance offered by the heatsink fins' surfaces may be at least partly responsible for the reduction in velocity of the airflow.

Various embodiments propose to change a shape of the air channels by using a convergent-divergent heatsink fin design. The fins in one embodiment are not parallel with each other. Rather, the fins may be angled inward toward a centerline of the heatsink. While a center fin may be straight or approximately straight, the other fins may be V-shaped. Taking one air channel as an example, it has its largest cross-section area at an edge of the heatsink, and that cross-section area decreases toward the centerline of the heatsink. The cross-section area increases on the other side of the centerline toward the other edge of the heatsink.

Various implementations increase a velocity of airflow closer to the centerline of the heatsink. Specifically, the smaller cross-section areas in the vicinity of the centerline of the heatsink may result in greater air velocity in the vicinity of the centerline of the heatsink. The greater velocity may result in increased heat removal. Put another way, the convergent-divergent arrangement of the fins causes a reduction in spacing between the fins along the direction of airflow to increase airflow velocity. The increased velocity may increase the heat transfer rate of the heatsink. Furthermore, the airflow velocity may be expected to be at a maximum at the narrowest portion of a given air channel, and computing systems may be designed to place a heat generating component nearest the narrowest portion of the air channels, thereby taking advantage of the greater airflow velocity.

Some implementations may include an information handling system (IHS), which includes a heat generating element, such as a processor, a peripheral card, or the like. The IHS may further include an air mover, such as a fan. The heat generating element may be physically coupled to a heatsink, where the fins of the heatsink are arranged to create air channels in a general direction of the airflow from the air mover.

One example may include implementing the heatsink to have a converging-diverging fin arrangement. Furthermore, the example may include implementing the heatsink as a passive heatsink, using the airflow from the system fan for convection heat removal.

Various implementations may provide advantages over prior solutions. For instance, various implementations may improve heat removal compared to prior systems having only parallel fins. Such implementations may provide increased heat removal at little to no extra cost for manufacture and use of the heatsinks.

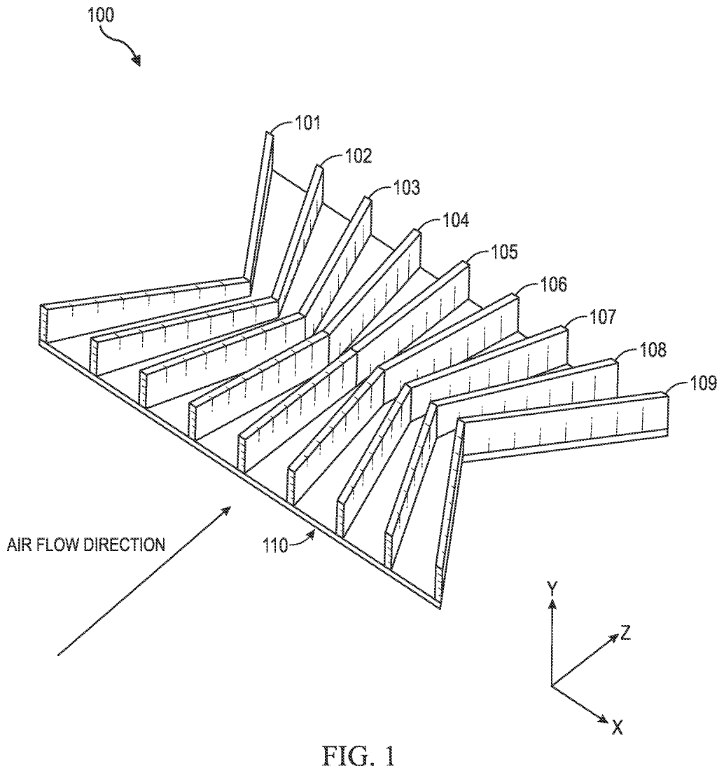

FIG. 1 is an illustration of an example heatsink 100, according to various embodiments. The illustration of FIG. 1 views heatsink 100 according to X, Y, and Z dimensions.

Heatsink 100 includes a flat base 110, which includes a six-sided polygon in the X-Z plane. Fins 101-109 are disposed upon a top surface of the base 110, and the fins extend from the top surface of the base 110 in the Y-axis direction. In this example, a height of the fins 101-109 in the Y-axis direction is greater than a thickness of the flat base in the Y-axis direction. FIG. 1 also illustrates a potential airflow direction. The fins 101-109 are arranged approximately parallel with the airflow direction. However, it is noted that the fins 101-109 are not arranged exactly parallel to the airflow direction, and the scope of implementations does not require exact parallel placement.

The fins 101-109 create multiple air channels for the airflow. For instance, fins 101 and 102 create a first air channel; fins 102 and 103 create a second air channel; fins 103 and 104 create a third air channel; fins 104 and 105 create a fourth air channel; fins 105 and 106 create a fifth air channel; fins 106 and 107 create a sixth air channel; fins 107 and 108 create a seventh air channel; and fins 108 and 109 create an eighth air channel.

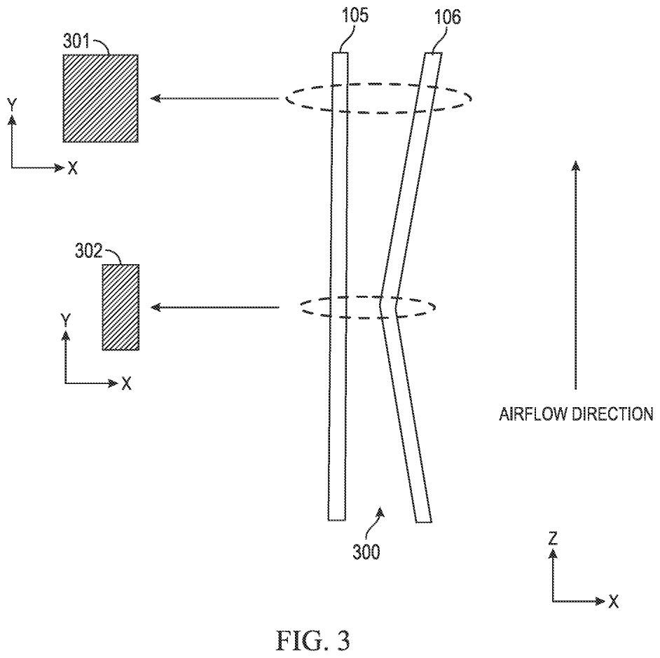

Each of the air channels is widest near an edge of the heatsink 100, and each of the air channels is narrowest toward a centerline of the heatsink 100. This is explained in more detail with respect to FIG. 3.

Heatsink 100 may be implemented using any appropriate material. For instance, heatsink 100 may benefit from a heat conductor, such as copper or aluminum, though other heat conductors may be appropriate for some applications. Furthermore, a heat conductor, such as copper or aluminum, may be milled, cast, or manufactured using any appropriate technique. Heatsink 100 may be a single piece of material or may be implemented from multiple pieces of material.

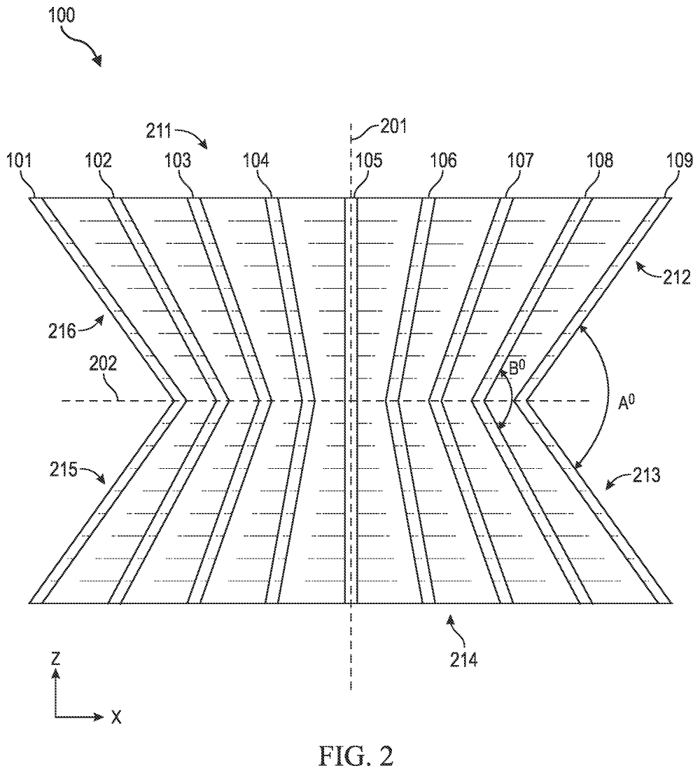

FIG. 2 is a wire diagram illustration of example heatsink 100, as depicted in a top-down view, according to various embodiments. As noted above, example heatsink 100 has a flat base 110, which is a six-sided polygon in the X-Z plane. The six sides are illustrated as sides 211-216. Furthermore, FIG. 2 illustrates two centerlines-a first centerline 201 and a second centerline 202. Example heatsink 100 is symmetric about an axis corresponding to centerline 201 and is also symmetrical about an axis corresponding to centerline 202.

Looking at centerline 202 first, the fins 101-109 are angled to converge with respect to each other as they approach centerline 202. Sides 212, 213 form a first V-shaped edge, and sides 215, 216 form a second V-shaped edge. Fin 109 is disposed at the first V-shaped edge, so that fin 109 conforms to the shape of the first V-shaped edge. Furthermore, fin 101 is disposed at the second V-shaped edge, and it conforms to the shape of the second V-shaped edge. The first V-shaped edge points inward toward the center of the heatsink 100, as does the second V-shaped edge.

Fin 105 is equidistant from fins 101 and 109, and fin 105 in this example is a straight line. In some examples, the number of fins may be an even number, in which case, a straight line fin may be omitted. In fact, number of fins, pitch of fins, angles of fins, height of fins (Y-axis) are examples of parameters that may be modified for a given application. Specifically, such parameters may be simulated, modified, simulated again, and eventually set to create acceptable performance for a given application.

In this example, each of the fins has an angle, and the angles of the fins are smaller as distance from centerline 201 increases. For instance, fin 109 and fin 101 have an angle of A degrees, whereas fin 108 and fin 102 have an angle of B degrees, where A is less than B. Similarly, the angles of fins 103 and 107 are greater than the angles of fins 102 and 108, and the angles of fins 104 and 106 are greater than the angles of fins 103 and 107. Fin 105 is formed as a straight line but may be considered to have an angle of 180°. In another example, the angles of the fins may be the same.

FIG. 3 is an illustration of an example air channel 300, according to the example embodiments illustrated in FIGS. 1 and 2. In the present example, air channel 300 is formed by fins 105 and 106. Fins 105 and 106 are illustrated in a top-down view (the X-Z axis). The air channel 300 is narrower toward centerline 202 of the heatsink and wider toward sides 211 and 214.

Example cross-section area 302 corresponds to centerline 202 of FIG. 2. Cross-section area 302 is illustrated in the edge-on view (Y-Z axis). Cross-section area 302 is illustrative of the area through which air flows as it traverses air channel 300 at centerline 202. By contrast, cross-section area 301 is closer to side 211 than to centerline 202. Cross-section area 301 is illustrative of the area through which air flows as the air approaches side 211. In the present example, the cross-section area 302 is narrower in the X dimension than is cross-section area 301. The narrowing illustrated in cross-section areas 301, 302 may result in a higher velocity of the airflow near centerline 202 than at either of the sides 211 or 214.

FIG. 3 illustrates example air channel 300, and it is understood that the other fins 101-109 create similar air channels. For instance, fins 108 and 109 create another air channel that narrows toward centerline 202 and widens toward sides 211, 214. Collectively, the air channels created by fins 101-109 allow the airflow to traverse the Z-axis length of the heatsink 100. The airflow may be provided by an air mover, such as a fan (not shown), and that movement of air may facilitate heat removal from the heatsink via convection.

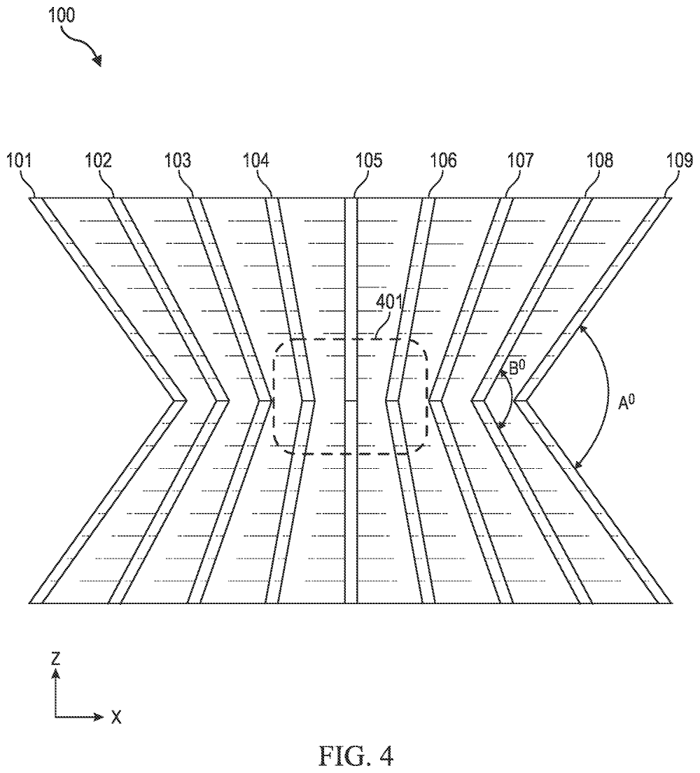

FIG. 4 is an illustration of example heatsink 100, according to various embodiments. Once again, heatsink 100 is shown in a top-down view in the X-Z plane. The fins 101-109 extend toward the viewer in the Y-axis (height) direction. The flat base 110 is below the fins 101-109 in the Y-axis direction.

Information handling resource 401 is illustrated in dashed lines to indicate that it is below the flat base in the Y-axis direction. In one example, the information handling resource 401 may be implemented as a semiconductor die package, and it may be fastened or adhered to the bottom surface of the flat base 110. For instance, information handling resource 401 may be adhered to a bottom surface of the flat base 110 using a heat-conducting adhesive. In another example, information handling resource 401 may be fastened to the bottom surface of the flat base 110 using a fastener, such as a set of screws. However, the scope of implementations is not limited to any technique to couple the information handling resource 401 to the flat base 110 of heatsink 100.

Examples of information handling resources may include processing units (e.g., central processing units or graphics processing units), application-specific integrated circuits, storage resources (e.g., solid-state drives, hard disk drives, redundant array of independent disks-RAID-devices), peripheral component interconnect express hardware, peripheral cards such as may be defined by Open Compute Project, platform controller hubs, memory devices, and other hardware that may generate heat in an IHS. Put another way, heatsink 100 may be coupled to an information handling resource, such as shown in FIG. 4, to remove heat from that information handling resource. However, the scope of implementations is not limited to any hardware device from which heat may be removed by heatsink 100.

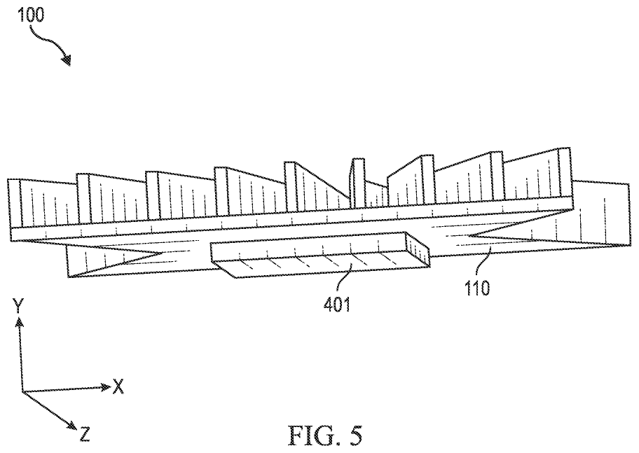

FIG. 5 is a perspective view of example heatsink 100, according to various embodiments. FIG. 5 provides a view of the bottom surface of flat base 110. Information handling resource 401 is shown coupled to the flat base 110 at the bottom surface.

Of note in FIGS. 4-5, the form factor of information handling resource 401 is smaller in surface area in the X-Z plane than is the flat base 110. In other words, the top surface of information handling resource 401 (the surface that couples to flat base 110) is completely covered by the bottom surface of flat base 110. In this example, the arrangement may facilitate heat removal by using the entire surface area of the top surface of information handling resource 401 for airflow contact.

Furthermore this example, information handling resource 401 is coupled to flat base 110 underneath the center of heatsink 110, as defined by centerlines 201, 202. The center of heatsink 110 is expected to experience the highest velocity of airflow through the air channels formed by the fins 101-109. In this manner, the placement of information handling resource 401 at the center of heatsink 100 is generally expected to take advantage of the increased heat removal along centerline 202 and thereby provide improved heat removal for information handling resource 401.

FIGS. 4-5 illustrate an example placement of information handling resource 401, and the scope of implementations is not limited to the specific placement of information handling resource 401, nor to the specific shape of information handling resource 401, nor to a number of information handling resources which may be coupled to a same heatsink. For instance, multiple information handling resources may be coupled to the flat base 110, in which case one or more of the information handling resources may be not placed at the very center of the heatsink 100, but the heat removal performance of the heatsink would generally be expected to be acceptable. Specifically, simulation may be used to design acceptable placement of one or multiple information handling resources with respect to a heatsink.

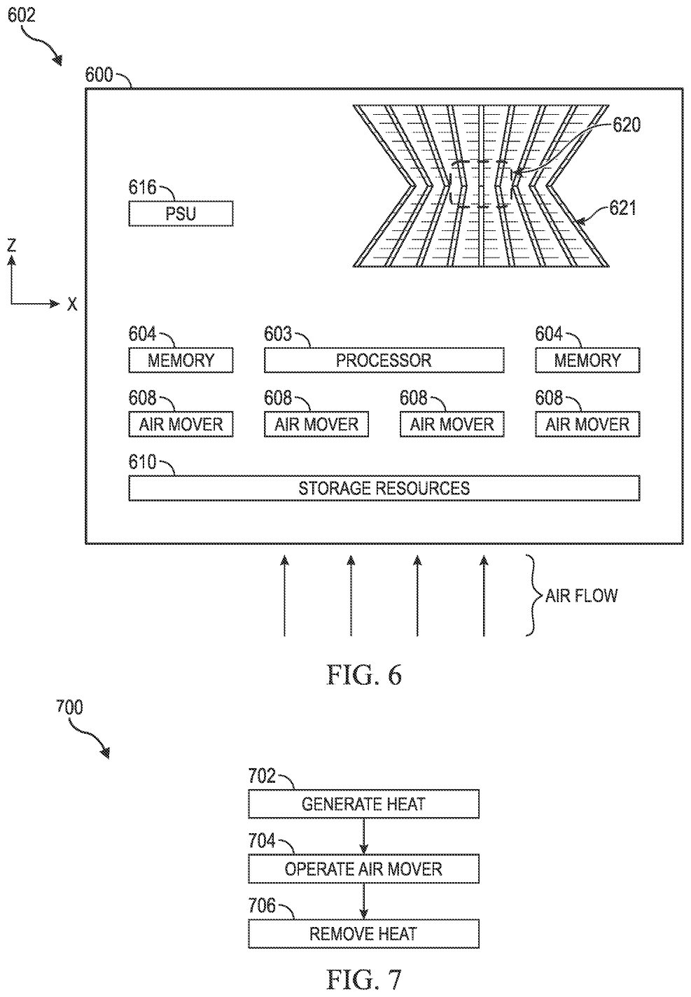

FIG. 6 illustrates a block diagram of selected components of an example information handling system 602, the block diagram representing a top-down view of the example information handling system, in accordance with embodiments of the present disclosure. In some embodiments, information handling system 602 may include a server chassis configured to house a plurality of servers or “blades.” In other embodiments, information handling system 602 may include a personal computer (e.g., a desktop computer, laptop computer, mobile computer, and/or notebook computer). In yet other embodiments, information handling system 602 may include a storage enclosure configured to house a plurality of physical disk drives and/or other computer-readable media for storing data. As shown in FIG. 6, information handling system 602 may include a chassis 600 housing a processor 603, memory 604, one or more air movers 608, storage resources 610, a power supply unit (PSU) 616, a peripheral complex 620.

Processor 603 may include any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 603 may interpret and/or execute program instructions and/or process data stored in memory 604 and/or another component of information handling system 602.

Memory 604 may be communicatively coupled to processor 603 and may include any system, device, or apparatus operable to retain program instructions or data for a period of time. Memory 604 may include random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 602 is turned off.

An air mover 608 may include any mechanical or electro-mechanical system, apparatus, or device operable to move air and/or other gases in order to cool information handling resources of information handling system 602. In some embodiments, system air mover 608 may include a fan (e.g., a rotating arrangement of vanes or blades which act on the air). In other embodiments, air mover 608 may include a blower (e.g., a centrifugal fan that employs rotating impellers to accelerate air received at its intake and change the direction of the airflow). In these and other embodiments, rotating and other moving components of system air mover 608 may be driven by a motor. The rotational speed of the motor may be controlled by an air mover control signal communicated from a thermal control system. In operation, system air mover 608 may cool information handling resources of information handling system 602 by drawing cool air into chassis 600 housing the information handling resources from outside chassis 600, expel warm air from inside chassis 600 to the outside of chassis 600, and/or move air across one or more heatsinks 621 internal to chassis 600 to cool one or more information handling resources.

Storage resources 610 may include one or more hard disk drives, magnetic tape libraries, optical disk drives, magneto-optical disk drives, compact disk drives, compact disk arrays, disk array controllers, and/or any other system, apparatus or device operable to store media. In some embodiments, storages resource 610 may include a plurality of physical storage resources that may appear to an operating system or virtual machine executing on information handling system 602 as a single logical storage unit or virtual storage resource. For example, each such virtual storage resource may include a RAID. Thus, in some embodiments, a virtual storage resource may include a redundant array of physical storage resources. In the same or alternative embodiments, a virtual storage resource may be implemented using a RAID standard. Although FIG. 6 depicts storage resources 610 internal to information handling system 602, in some embodiments, storage resource 610 may be external to information handling system 602 (e.g., embodied by a physical array of external hard disk drives).

PSU 616 may include any suitable system, device, or apparatus for delivering electrical energy to electrical and electronic components of information handling system 602 in order to enable such components to carry out their respective functionality. Thus, PSU 616 may include one or more of an alternating current-to-direct current (AC/DC) power converter, direct current-to-direct current (DC/DC) power converter, battery, or any other suitable device.

Heatsink 621 is adapted based on the principles discussed above with respect to heatsink 100 of FIGS. 1-5. Specifically, heatsink 621 has multiple fins, which create a converging-diverging pattern and, thus, provide air channels, such as described above with respect to FIG. 3. Furthermore, heatsink 621 is coupled to peripheral complex 620 in a same or similar way as heatsink 100 is coupled to information handling resource 401 in the example of FIG. 4.

While heatsink 621 is shown as only being coupled to peripheral complex 620, it is understood that a heatsink, adapted based on the principles of example heatsink 100, may be coupled to any one, some, or all of the components 603, 604, 610, 616, as appropriate for a given system.

Peripheral complex 620 may include one or more other information handling resources, including without limitation co-processors, graphics processors, buses, memories, I/O devices and/or interfaces, storage resources, network interfaces, motherboards, integrated memory devices, circuit packages, electro-mechanical devices, displays, and/or other devices.

In addition to processor 603, memory 604, one or more air movers 608, storage resources 610, a power supply unit (PSU) 616, a peripheral complex 620, and fluidic conduits 126, information handling system 602 may include one or more other information handling resources.

In operation, air movers 608 shown in FIG. 1 may cause air to be drawn in from a “front” of information handling system 602 (e.g., the bottom edge of chassis 600 as shown in FIG. 1), with air flowing proximate to storage resources 610, through air movers 608, such that air movers 608 may further drive airflow proximate to processor 603, memory 604, PSU 616, and through the air channels provided by the fins of heatsink 621.

Heatsink 621 may be implemented on an information handling resource in a server, a laptop computer, a desktop computer, or other IHS.

FIG. 7 is an illustration of an example method 700 for heat removal in an IHS, according to various embodiments. The actions of method 700 may be performed by an IHS, such as example IHS 602 of FIG. 6.

At action 702, the IHS generates heat from an information handling resource. For instance, the information handling resource may be powered on and operating, thereby generating heat. Furthermore, in this example, the information handling resource is coupled to a heatsink, such as heatsink 100 or 621.

At action 704, the IHS operates an air mover. For instance, the air mover may create airflow, which is directed through a plurality of fins of the heatsink. As noted above with respect to FIGS. 1-6, the fins are configured to create a plurality of air channels that are narrower toward a centerline of the heatsink and wider toward a first edge and a second edge of the heatsink. Air channels and airflow are discussed in more detail above with respect to FIG. 3.

At action 706, the IHS removes heat. For instance, the airflow through the air channels of the heatsink may remove heat from the information handling resource that is coupled to the heatsink.

Of course, the scope of implementations is not limited to the series of actions 702-706. Rather, the scope of implementations may include performing method 700 continually, periodically, or multiple times over a period of time. In one example, the IHS may have a thermal management algorithm that operates the air mover, as in action 704, at certain times and as appropriate to remove heat from the information handling resource. The scope of implementations is not limited to any particular thermal management algorithm, and the scope of implementations is not limited to including a specific thermal management algorithm. For instance, in always-on air mover may be used in various embodiments as appropriate.

It should be understood that various operations described herein may be implemented in software executed by logic or processing circuitry, hardware, or a combination thereof. The order in which each operation of a given method is performed may be changed, and various operations may be added, reordered, combined, omitted, modified, etc. It is intended that the implementation(s) described herein embrace all such modifications and changes and, accordingly, the above description should be regarded in an illustrative rather than a restrictive sense.

Although the implementation(s) is/are described herein with reference to specific embodiments, various modifications and changes can be made without departing from the scope of the present implementation(s), as set forth in the claims below. Accordingly, the specification and figures are to be regarded in an illustrative rather than a restrictive sense, and all such modifications are intended to be included within the scope of the present implementation(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. An information handling system (IHS) comprising:
an information handling resource;
a heatsink, coupled to the information handling resource, wherein the heatsink comprises a plurality of fins on a side of the heatsink away from the information handling resource, wherein the plurality of fins are configured to create a plurality of air channels that are narrower toward a center of the heatsink and wider toward a first edge and a second edge of the heatsink; and
an air mover configured to drive airflow through the air channels.

2. The IHS of claim 1, wherein the information handling resource comprises a semiconductor die housed in a package, further wherein the heatsink is coupled directly to the package.

3. The IHS of claim 2, wherein the information handling resource comprises a processing unit.

4. The IHS of claim 2, wherein the information handling resource comprises a peripheral device.

5. The IHS of claim 2, wherein the information handling resource comprises a storage drive.

6. The IHS of claim 1, further comprising:
a chassis, wherein the information handling resource and the heatsink are disposed within the chassis.

7. The IHS of claim 1, wherein the first edge and the second edge of the heatsink are parallel, further wherein the first edge and the second edge are straight and a third edge and a fourth edge of the heatsink are V-shaped.

8. The IHS of claim 7, wherein the air mover is arranged to drive the airflow perpendicular to the first edge and the second edge.

9. The IHS of claim 7, wherein the heatsink is symmetric about a first axis, wherein the first axis extends between the third and edge and the fourth edge.

10. The IHS of claim 7, wherein the heatsink is symmetric about a second axis, wherein the second axis extends between the first edge and the second edge.

11. A heatsink comprising:
a flat base, wherein the flat base is configured as a six-sided polygon having a first side parallel to a second side, a third side and a fourth side forming a first V shape pointing inward toward a center of the heatsink, and a fifth side and a sixth side forming a second V shape pointing inward toward the center; and
a plurality of fins coupled to the flat base, the plurality of fins converging from the first side toward a centerline of the heatsink and diverging from the centerline to the second side.

12. The heatsink of claim 11, wherein the heatsink is a single piece of aluminum.

13. The heatsink of claim 11, wherein the plurality of fins comprises:
a first fin conforming to the first V shape and arranged at the third side and the fourth side; and
a second fin conforming to the second V shape and arranged at the fifth side and the sixth side.

14. The heatsink of claim 13, wherein the plurality of fins further comprises:
a third fin, equidistant between the first fin and the second fin, wherein the third fin is configured as a straight line extending from the first side to the second side.

15. The heatsink of claim 14, wherein the plurality of fins further comprises:
a fourth fin, disposed between the first fin and the third fin, the fourth fin having a first angle, wherein the third side and the fourth side form a second angle smaller than the first angle.

16. The heatsink of claim 15, wherein the plurality of fins further comprises:
a fifth fin, disposed between the second fin and the third fin, the fifth fin having the first angle, wherein the third side and the fourth side form the second angle.

17. The heatsink of claim 11, wherein each of the fins have a same height, and wherein the height is greater than a thickness of the base.

18. A method comprising:
generating heat from an information handling resource in an information handling system (IHS), wherein the information handling resource is coupled to a heatsink; and
operating an air mover to create airflow within the IHS, wherein the airflow is directed through a plurality of fins of the heatsink, wherein the fins are configured to create a plurality of air channels that are narrower toward a center of the heatsink and wider toward a first edge and a second edge of the heatsink.

19. The method of claim 18, further comprising:
removing heat from the information handling resource via the airflow.

20. The method of claim 18, wherein the information handling resource comprises a peripheral device, and wherein generating heat from the information handling resource includes powering on and operating the peripheral device.
